(19) United States
(12) Patent Application Publication
(10) Pub. No.: US 2013/0022752 A1
(43) Pub. Date: Jan. 24, 2013

(54) METHODS FOR TREATING A SURFACE OF A SUBSTRATE BY ATMOSPHERIC PLASMA PROCESSING

(71) Applicant: DAPHNE PAPPAS ANTONAKAS, Ellicott City, MD (US)

(72) Inventor: DAPHNE PAPPAS ANTONAKAS, Ellicott City, MD (US)

(73) Assignee: U.S. Government as represented by the Secretary of the Army, Adelphi, MD (US)

(21) Appl. No.: 13/553,353

(22) Filed: Jul. 19, 2012

Related U.S. Application Data
(60) Provisional application No. 61/509,789, filed on Jul. 20, 2011.

(51) Int. Cl. B05D 3/10; B05D 1/18; C23C 14/34; B05D 1/02; C23C 16/02; C23C 16/50

(52) U.S. Cl. 427/444; 427/535

(57) ABSTRACT

Methods for treating a surface of a substrate are disclosed herein. In some embodiments, a method includes forming reactive sites on the surface of the substrate by exposing the surface of the substrate to a first atmospheric plasma formed from a first process gas comprising an inert gas; and functionalizing the reactive sites by exposing the surface of the substrate to a second atmospheric plasma formed from a second process gas comprising the inert gas and water vapor (H₂O).

### CROSS-REFERENCE TO RELATED APPLICATIONS

This application is related to and claims priority from co-pending U.S. Provisional Patent Application No. 61/509,789 filed on Jul. 20, 2011 by inventor Daphne Pappas-Antonakas and titled “Atmospheric Plasma Process” which is hereby incorporated herein by reference in its entirety including all attachments, appendices and figures filed with U.S. Provisional Patent Application No. 61/509,789.

### GOVERNMENT INTEREST

Governmental Interest—The invention described herein may be manufactured, used and licensed by or for the U.S. Government.

### FIELD OF INVENTION

Embodiments of the present invention generally relate to atmospheric plasma processing and, more particularly, to methods for treating a surface of a substrate by atmospheric plasma processing.

### BACKGROUND OF THE INVENTION

Processes for forming an active surface on a substrate, such as corona plasmas, wet chemical treatments, for example, using chromic acid, and so forth can improve hydrophilicity on a treated surface immediately after treatment. Unfortunately, over time a surface treated by these processes become less hydrophilic, thus rendering these surfaces inactive for further treatment. Further, the above mentioned methods can involve non-environmentally friendly processes which may generate hazardous waste.

Therefore, the inventor has provided improved methods of forming stable active surfaces on a substrate.

### BRIEF SUMMARY OF THE INVENTION

Methods for treating a surface of a substrate are disclosed herein. In some embodiments, a method may include forming reactive sites on the surface of the substrate by exposing the surface of the substrate to a first atmospheric plasma formed from a first process gas comprising an inert gas; and functionalizing the reactive sites by exposing the surface of the substrate to a second atmospheric plasma formed from a second process gas comprising the inert gas and water vapor (H₂O).

In some embodiments, a method for treating the surface of a substrate may include forming radicals on the surface of the substrate by exposing the surface to a first atmospheric plasma formed from a first process gas comprising an inert gas to break chemical bonds on the surface, wherein a first portion of the radicals form reactive sites on the surface and a second portion of the radicals form protective sites on the surface; functionalizing the reactive sites formed by the first atmospheric plasma by exposing the surface of the substrate to a second atmospheric plasma formed from a second process gas comprising the inert gas and water vapor (H₂O); and forming a layer on the functionalized surface of the substrate by exposing the surface of the substrate to a layer forming species during or after exposure to the second atmospheric plasma.

Other and further embodiments of the present invention are discussed below.

### BRIEF DESCRIPTION OF THE DRAWINGS

So that the manner in which the above recited features of the present invention can be understood in detail, a more particular description of the invention, briefly summarized above, can be made by reference to embodiments, some of which are illustrated in the appended drawings. It is to be noted, however, that the appended drawings illustrate only certain exemplary embodiments of this invention and are therefore not to be considered limiting of its scope, for the invention may admit to other equally effective embodiments.

FIG. 1 depicts a flow chart of a method for treating the surface of a substrate in accordance with some embodiments of the present invention.

FIGS. 2A-E respectively schematically depict the stage of treating the surface of a substrate in accordance with some embodiments of present invention.

FIG. 3 depicts an atmospheric plasma apparatus in accordance with some embodiments of the present invention.

### DETAILED DESCRIPTION OF THE INVENTION

Embodiments of the present invention comprise methods for treating the surface of a substrate. The inventive methods may be utilized with one or more of metal, ceramic, composite or other hybrid materials or polymer surfaces to form an active surface which may be chemically modified, such as by tethering molecules to form a self assembled monolayer, or have improved adhesive properties when depositing thin conformal coatings via chemical vapor deposition, spray deposition, spin coating, dip coating and so forth. The inventive methods may advantageously produce little or no environmental harmful waste materials and further may form a stable active surface which may be stored under atmospheric conditions for periods of time while still retaining the active surface. Thus, in certain desirable embodiments the present invention provides an environmentally friendly method for treating the surface of a material with a plasma to change the surface morphology and chemical composition as well as the physical and chemical properties. Other and further advantages of the present invention are discussed below.

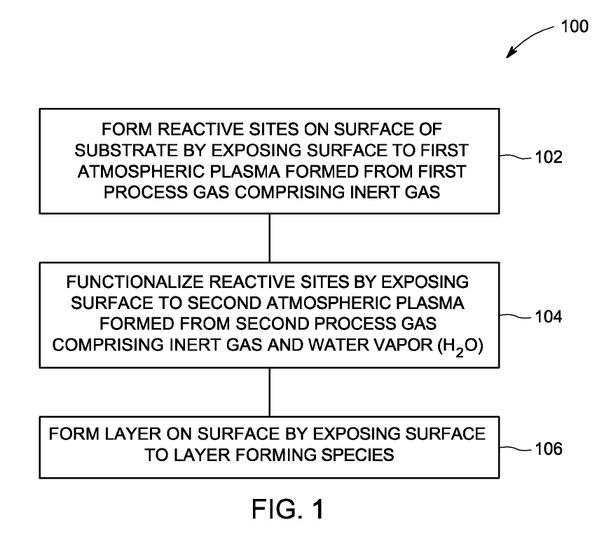

FIG. 1 depicts a flow chart for a method 100 for treating a surface of a substrate in accordance with some embodiments of the present invention. The method 100 is described below in accordance with stages of treating a substrate 200 in accordance with some embodiments of the present invention. For example, the substrate 200 may comprise one or more of a polymer, a metal, or a ceramic. Exemplary polymers include, but are not limited to, one or more of polyolefins such as polyethylene and ultra high molecular weight polyethylene (UHMWPE), polyamides, polyesters such as polyethylene terephthalate (PET), polyimides, fluorocarbons such as polytetrafluoroethylene (PTFE), and so forth. Any of the exemplary polymers may be in any suitable configuration, such as linear, synthesized copolymers, branched and so forth. Exemplary metals include, but are not limited to, one or more of copper (Cu), magnesium (Mg), and so forth. Exemplary ceramics include, but are not limited to, one or more of alumina (Al₂O₃), silicon carbide (SiC), and so forth.

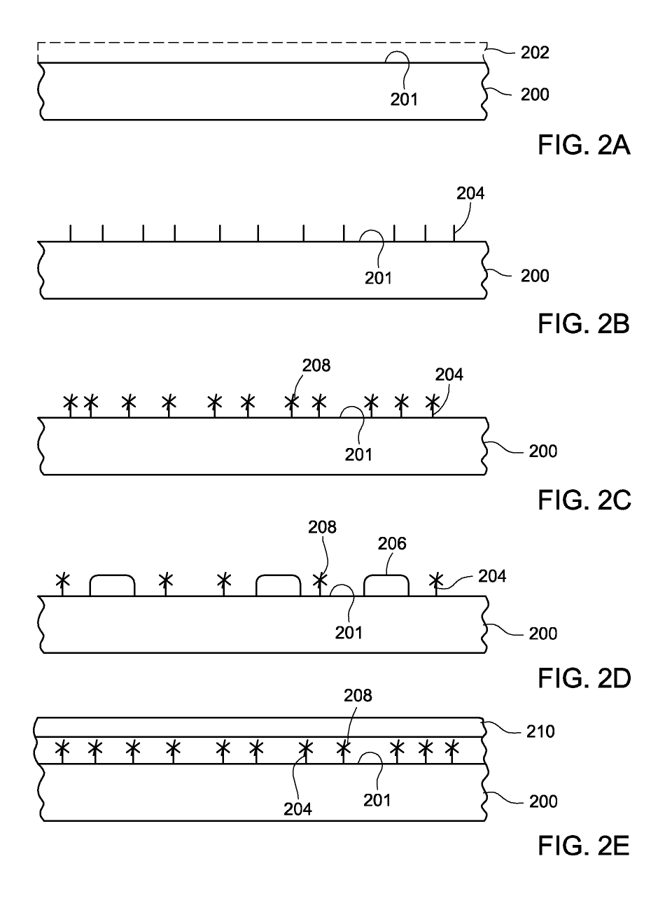

A surface 201 of the substrate 200 is illustrated in FIG. 2A. The surface 201 may vary depending on a composition of the substrate 200. For example, the surface 201 may include a plurality of polymer chains when the substrate 200 comprises a polymer. For example, the plurality of polymer chains may be arranged in any suitable configuration, such as semi-crystalline, amorphous, and so forth. In some embodiments, the plurality of polymers may have few or no reactive sites.

In some embodiments, the surface 201 may include a coating 202. In embodiments where the substrate comprises a metal, the coating 202 may be a metal oxide. For example, the metal oxide may inhibit reactivity with the underlying surface 201 and may need to be removed prior to functionalizing the surface 201. Alternatively or in combination, surface contaminants from handling or processing may be disposed on the surface 201 and may be removed through the proposed processes discussed herein. In embodiments where the substrate 200 comprises a ceramic, the coating 202 may include a glassy phase. For example, similar to the metal oxide discussed above, the glassy phase may inhibit reactivity with the underlying surface 201 and may need to be removed prior to functionalizing the underlying ceramic surface.

The method 100 generally begins at 102 by forming reactive sites 204 on the surface 201 of the substrate by exposing the surface 201 of the substrate to first atmospheric plasma formed from a first process gas comprising an inert gas. As used herein, the term “atmospheric plasma” includes a plasma formed under ambient pressure conditions, for example a pressure of about 1 atmosphere (atm), or at pressures ranging from about 0.1 atm to about 5 atm. In some embodiments, atmospheric plasmas used herein may be formed under ambient pressure conditions, ambient temperature and/or humidity conditions. Exemplary ambient pressure conditions, include the range of from about 550 Torr to about 850 Torr, from about 600 Torr to about 800 Torr from about 650 Torr to about 800 Torr, from about 700 Torr to about 800 Torr, from about 725 Torr to about 800 Torr and from about 750 Torr to about 780 Torr. Thus, in certain embodiments the method of the present invention operates at a pressure of greater than 550 Torr, greater than 600 Torr, greater than 650 Torr, greater than 700 Torr, greater than 725 Torr and even greater than 750 Torr. Exemplary temperature conditions range from about to about 0° C. to about 50° C., from about 5° C. to about 40° C., from about 10° C. to about 30° C. and from 20° C. to about 30° C. Exemplary ambient humidity conditions may range from about 10 percent to about 90 percent, from about 20 percent to about 80 percent and from about 30 percent to about 70 percent. In certain embodiments, the method of the present invention operates at a relative humidity of greater than 50 percent, greater than 60 percent, greater than 70 percent and even greater than 80 percent relative humidity. The substrate 200 including the reactive sites 204 is illustrated in FIG. 2B. For example, the inert gas may include one or more of helium (He), neon (Ne), argon (Ar), krypton (Kr), xenon (Xe), and Radon (Rn), and optionally, hydrogen (H₂), nitrogen (N₂), or air and any combinations thereof at any desired ratios. For example, the first process gas may be applied at any suitable flow rate, such as from about 10 sccm (standard cubic centimeters per minute) to about 100 liters per minute. For example, the amount of reactive sites 204 formed may be controlled such as by varying one or more of the flow rate of the first process gas, the flow direction of the first process gas, the temperature of the substrate 200, the density of the first atmospheric plasma, the power of the first atmospheric plasma, the duration of exposure to the first atmospheric plasma, the geometry of the electrodes, the size of the electrodes, the distance between the substrate and the electrodes and so forth.

The reactive sites 204 may exist on the surface 201 of the substrate 200, for example, such as underlying a metal oxide or a glassy phase as discussed above. Accordingly, forming the reactive sites may include removing impurities, such as the aforementioned surface contaminants, metal oxides or glassy phases, on the surface 201 of the substrate 200 using the first atmospheric plasma to expose the reactive sites 204 on the surface.

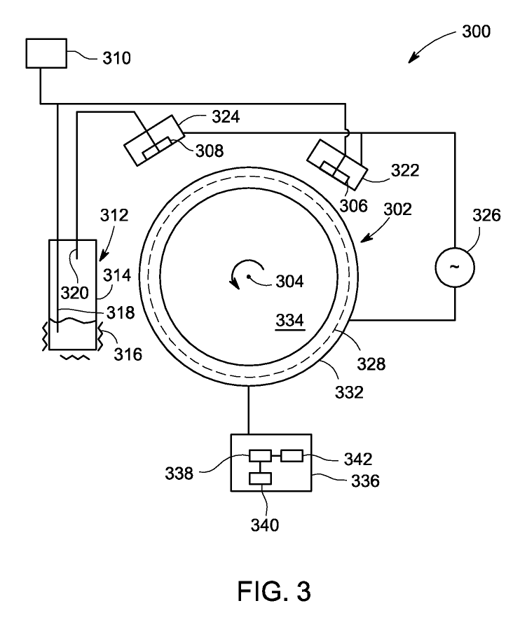

Alternatively, for example, when the substrate comprises a polymer, forming the reactive sites 204 may include forming radicals on the surface of the substrate by breaking chemical bonds using the first atmospheric plasma, wherein in at least a first portion of the radicals form the reactive sites 204. In some embodiments, for example, when the substrate comprises a polymer, protected sites 206 may be formed by crosslinking at least a second portion of the radicals. The protected sites 206 are illustrated in FIG. 2D. A ratio of reactive sites 204 to protected sites 206 on the surface 201 of the substrate 200 may be controlled by adjusting one or more of the flow rate of the first process gas, the flow direction of the first process gas, the temperature of the substrate, the density of the first atmospheric plasma, the power of the first atmospheric plasma, the size of electrodes (discussed below and illustrated in FIG. 3) used to form the first atmospheric plasma, the geometry of the electrodes, the distance between the substrate and the electrodes the duration of exposure to the first atmospheric plasma, and so forth. For example, the ratio may be used to control adhesive or reactive properties of the surface 201, for example, by controlling the number of reactive site 204 or by controlling the environment around the reactive sites 204 such that molecules of a specific size and/or geometry can be coupled to the reactive sites 204.

Alternatively or in combination with embodiments discussed above and/or below, the first atmospheric plasma and/or the second atmospheric plasma (discussed below) can cause the appearance of textured surfaces, for example through the formation of microdepressions (pitting). Accordingly, the resulting surface 201 may be can be rougher or smoother after the plasma treatment. The roughened or smoothed surface resultant from plasma treatment may be utilized to control adhesion of layers on the surface 201.

At 104, the reactive sites 204 may be functionalized by exposing the surface of the substrate to a second atmospheric plasma formed from a second process gas comprising the inert gas and water vapor (H₂O). In certain desirable embodiments water vapor is purposely introduced into the process, for example via the use of ambient air that is present in a facility in which the process is conducted. Thus, in certain embodiments the second process gas has an absolute humidity or a relative humidity of greater than about 5 percent, greater than about 10 percent, greater than about 20 percent, greater than about 40 percent and even greater than about 50 percent. In certain embodiments, water is provided at a water vapor mass fraction of at least about 30 mg·g⁻¹ of gas mixture, at least about 40 mg·g⁻¹ of gas mixture, at least about 50 mg·g⁻¹ of gas mixture, at least about 55 mg·g⁻¹ of gas mixture and even at least about 65 mg·g⁻¹ of gas mixture. A functional portion 208 of the reactive site 204 is illustrated in FIGS. 2C-D. In some embodiments, functionalizing the reactive sites 204 may include removing impurities 201 on the surface 201 of the substrate 200 using the second atmospheric plasma.

Alternatively, the functional portion 208 may be formed on the reactive sites 204 of any of a metal, ceramic, composite material, or polymer. For example, in some embodiments, such as where the reaction sites 204 are radicals as discussed above, the radicals may react with the second atmospheric plasma to form the functional portion 208. For example, the functional portion 208 may comprise a functional group such as one or more of a hydroxyl group, a ketone group, carbonyl group, a carboxylic acid group and so forth. In some embodiments, water vapor may be substituted or used in combination with additional oxygen-containing gases to form the desired functional portion 208. Exemplary oxygen-containing gases may include one or more of carbon dioxide (CO₂), air, nitrous oxide (N₂O), and so forth. For example, the type of functional group formed at the reactive sites may be controlled by adjusting one or more of the ratio of the inert gas to water vapor in the second process gas, the temperature of the substrate, the density and/or power of the second atmospheric plasma, distance between the substrate and one or more electrode used to form the second atmospheric plasma, the size of the electrodes, the geometry of the electrodes or a duration of exposure to the second atmospheric plasma.

At 106, a layer 210 may be formed on the surface 201 of the substrate 200 by exposing the surface 201 of the substrate 200 to a layer forming species, as illustrated in FIG. 2E. Only one specific embodiment of the layer 210 is illustrated in FIG. 2E where the layer 210 is coupled to the functionalized surface 201. However, other embodiments are possible as discussed below, for example, where the functional portions 208 are reacted to form the layer 210 and/or where the functionalized surface 201 includes at least some protected sites 206, which are not illustrated in FIG. 2E.

The layer forming species may be included in the second atmospheric plasma or alternatively, the surface of the substrate may be exposed to the layer forming species after exposure to the second atmospheric plasma. Exemplary layer forming species may include one or more of isocyanate or isocyanate-based adhesives, urethane, vinyl ester, adhesives, such as epoxy-based adhesives, alkylsilanes, perfluoroalkylsilanes, oxides, or polymers.

In some embodiments, the layer forming species may be included in the second process gas. For example, when the surface 201 is exposed to the second atmospheric plasma including the layer forming species, the second atmospheric plasma may react with the reactive sites 204 to form the functional portions 208 and further react the functionalized reactive sites with the layer forming species to form the layer 210 on the surface 201 of the substrate 200.

The functionalized reactive sites may be reacted with the layer forming species to form a bond between the functionalized reactive sites and the layer forming species. For example, a functional portion 208 including a hydroxyl group may react with an isocyanate-based adhesive to create a polyurethane layer (e.g., layer 210). For example, a functional portion 208 including a hydroxyl group may react with alkylsilanes, perfluoroalkylsilanes, or any suitable alkylsilane derivatives to form a self assembled monolayer (SAM) (e.g., layer 210) on the surface 201. For example, the SAM may act as a moisture barrier and so forth.

Alternatively, the layer 210 may be formed on the surface 201 of the substrate 200 from the layer forming species using one or more of chemical vapor deposition, physical vapor deposition, sputtering, spray deposition, casting, spin coating, or dip coating. For example, the functionalized surface of the substrate 200 may provide an improved adhesive surface to form the layer 210 from the layer forming species using any of the aforementioned deposition methods. For example, in methods such as chemical vapor deposition, spray deposition, spin coating, dip coating and so forth, the layer 210 may be physically adhered to the surface 201 for example, by short range dipole-dipole interactions, physical entanglement of molecules between the surface 201 and the layer 210, or any other suitable types of physical interactions, such as those that do not involve chemical bonding. Alternatively, chemical bonding may occur during formation of the layer 210 using one or more of the aforementioned deposition methods discussed above.

FIG. 3 depicts an atmospheric plasma apparatus 300 in accordance with some exemplary embodiments of the present invention. The atmospheric plasma apparatus 300 may be a dielectric barrier discharge (DBD) type plasma apparatus and so forth. The apparatus 300 may include a substrate support 302. The substrate support may be rotatable about a central axis 304 such that a substrate present on the substrate support 302 passes under a first gas outlet 306 followed by a second gas outlet 308. The first and second gas outlet 306, 308 may be coupled to an inert gas source 310 for providing an inert gas to each of the first and second gas outlet 306 and 308, respectively. The second gas outlet 308 may be coupled to the inert gas source via an evaporator 312, such that an inert gas from the inert gas source 310 may flow through the evaporator 312, mix with gases in the evaporator 312, and the mixture of the inert gas and the evaporated gas may be provided to the second gas outlet 308. In one exemplary embodiment, the evaporated gas provided to the second gas outlet is water vapor that is produced from evaporated water.

The evaporator 312 may include a vessel 314 for holding a material to be evaporated, such as water (H2O), aqueous liquid solutions, organic solvent based solutions and so forth. The vessel 314 may include heaters 316 for heating the material within the vessel such that the inorganic or organic liquid precursor material evaporates. The inert gas may enter the vessel 314 via an outlet 318 and a mixture of inert gas and evaporated liquid may exit the vessel 314 via an outlet 320 coupled to the second gas outlet 308. Embodiments of the evaporator 312 are merely exemplary and other embodiments of an evaporator or other apparatus for providing a gas mixture to the second electrode 308 may be possible.

Each of the first and second gas outlets 306, 308 may include an electrode 322, 324 used to form plasmas from gases exiting the first and second gas outlets 306, 308 respectively. For example, each electrode 322, 324 may be coupled to a power source 326. The power source 326 may be further coupled to a ground electrode 328 disposed in the substrate support 302. A capacitively coupled plasma may be formed between each of the first and second electrodes 306, 308 and the ground electrode 328. The power source may provide radio frequency (RF) or microwave frequency (MF) power. A dielectric layer 332 may be disposed between a substrate 334 and the ground electrode 328. Alternatively, (not shown) the dielectric layer may be a plurality of dielectric layers disposed between each of the first and second electrodes 306, 308 and the substrate 334. Other and further suitable configurations of a dielectric barrier discharge atmospheric plasma apparatus may be utilized.

A controller 336 may be coupled to various components of the apparatus 300 to control the operation thereof. Although schematically shown coupled to the substrate support 302, the controller may be operably connected to any component that may be controlled by the controller, such as the power source 326, the evaporator 312, the inert gas source 310, and so forth, in order to control the apparatus 300 in accordance with methods disclosed herein. The controller 336 generally comprises a central processing unit (CPU) 338, a memory 340, and support circuits 342 for the CPU 338. The controller 336 may control the apparatus 300 directly, or via other computers or controllers (not shown) associated with particular support system components. The controller 336 may be one of any form of general-purpose computer processor that can be used in an industrial setting for controlling various chambers and sub-processors.

The memory, or computer-readable medium, 340 of the CPU 338 may be one or more of readily available memory such as random access memory (RAM), read only memory (ROM), floppy disk, hard disk, flash, or any other form of digital storage, local or remote. The support circuits 342 are coupled to the CPU 338 for supporting the processor in a conventional manner. These circuits include cache, power supplies, clock circuits, input/output circuitry and subsystems, and the like. Inventive methods as described herein may be stored in the memory 340 as a software routine that may be executed or invoked to turn the controller into a specific purpose controller to control the operation of the apparatus 300 in the manner described herein. The software routine may also be stored and/or executed by a second CPU (not shown) that is remotely located from the hardware being controlled by the CPU 338.

In operation, the substrate 200 may be placed on the substrate support 302 and rotated about the central axis 304. The first outlet 306 may provide the first process gas and the first atmospheric plasma may be formed by providing power from the power source 326 to the first electrode 322 and the ground electrode 328. The second outlet 308 may provide the second process gas and the second atmospheric plasma may be formed by providing power from the power source 326 to the second electrode 324 and the ground electrode 334. The first and second atmospheric plasmas may be provided in parallel or serially. For example, in a parallel configuration, the substrate 200 may be simultaneously exposed to the first and second atmospheric plasmas while rotating about the central axis 304. Alternatively, the substrate 200 may be exposed to the first atmospheric plasma for any desired number of rotations about the central axis and/or any desired period of time to create reactive sites 204 on the surface 201; and then the substrate 200 may be exposed to the second atmospheric plasma for any desired number of rotations about the central axis 304 and/or any desired period of time to functionalize the reactive sites 204 and/or form the layer 210 on the surface 201 of the substrate 200.

Other embodiments of the apparatus are possible, for example, the apparatus may include a conveyor belt and so forth instead of the substrate support 302, where the substrate 200 moves on the conveyor belt past the first and second outlets 306, 308.

### EXAMPLES

Examples of polymer films that were modified with water vapor and helium gas by a method of the present invention are described in a journal article titled “Atmospheric Plasma Processing of Polymers in Helium-Water Vapor Dielectric Barrier Discharges” by Victor Rodriguez-Santiago, Andres A. Bujanda, Benjamin E. Stein and Daphne D. Pappas of the U.S. Army Research Laboratory in Plasma Process. Polym. 2011, 8, 631-639 which is hereby incorporated by reference. The Experimental Section is repeated below.

### Plasma Treatment

The plasma system used in these experiments was an APC 2000 from Sigma Technologies Intl. Inc. The system uses a cylindrical roller configuration and it is operated in an open atmosphere setup as generally illustrated in FIG. 3. The roller serves 328 as the ground electrode and it is covered with Al₂O₃ as the dielectric material. Two high voltage electrodes 322 and 324 are positioned on top of the roller at a distance of 2 mm, and have slit channels to allow gas diffusion. The flow rate for the carrier gas, in this case He, was 200 cm³·s⁻¹, and it was equally divided with one line going directly to one of the electrodes 322, and another line going to an evaporator that was used to supply the reactive gas, in this case water vapor, to the other electrode 324. The amount of water vapor entrained in the He gas stream can be controlled by changing the temperature and flow of the carrier gas in the evaporator. In this study, the temperature of the evaporator was kept at 25° C. which provided a water vapor mass fraction of 65.2 mg·g⁻¹ of gas mixture. For these experiments, one electrode 322 was used for pre-treatment using the carrier gas and the other electrode 324 was used for functionalization purposes using the reactive gas. A radio-frequency power supply operating at 90 kHz was used, with power densities ranging between 0.861 and 2.58 W·cm⁻². Under these conditions the plasma generated was mostly uniform; however, the presence of microdischarges was inevitable. Samples were taped to the rotating cylindrical dielectric surface, and the plasma exposure time was varied by changing the rotating speed of the roller. Plasma exposure times ranged between 0.4 and 40 s.

### Materials

Ultrahigh molecular weight polyethylene (UHMWPE) and PET with thickness of 75 μm, and PTFE films with thickness 1 mm (Goodfellow Co.) were cut into 2.5 cm×5 cm strips. The samples were rinsed with ethanol to remove surface residual contamination and were let to dry in air prior to plasma exposure. These three polymers were chosen for their different chemical structures to help define the extent of plasma modification. Polyethylene is a material that has been widely used and studied and is chosen as a simple-structure model polymer. PTFE is a polymer complementary to polyethylene but the presence of C—F bonds provides unique properties. PET intrinsically contains structurally bonded oxygen in its structure prior to plasma treatment. Therefore, it was of particular interest to study the plasma efficacy on an aromatic oxygen-containing polymer.

### Surface Characterization

Within 5 min after the plasma treatments wettability testing was carried out using a static contact angle setup and by applying the sessile drop method, as described elsewhere. The liquids used for contact angle measurements were deionized water, dimethyl formamide, and diiodomethane that were chosen for their wide polarity range. Six drops (5 μL each) for each of the test liquids were used on each control and plasma-treated sample, and the values averaged to obtain a representative contact angle value. The surface energy values were calculated using Good and Girifalco's approach.

$$\frac{\text{?} ( 1 + \text{?} )}{2 \sqrt{\text{?}}} = \sqrt{\text{?}} \sqrt{\text{?}} + \sqrt{\text{?}} \\ \text{?} \text{indicates text missing or illegible when filed} \qquad ( ( 1 ) )$$

where γ_{L} is the surface energy of the liquid, θ the solid-liquid contact angle, and γ_{S} is the surface energy of the polymer. The superscripts d and p denote the dispersive and polar components, respectively, of the surface energy. The dispersive component represents the induced-dipole/induced-dipole-type interactions (London dispersive forces), and the polar component relates to the dipole/dipole and dipole/induced-dipole-type interactions (Keesom and Debye forces). An interpolation of versus for multiple test liquids yields a linear fit with slope √ and intercept √. Squaring and adding these two values gives the total surface tension of the solid. For the aging experiments, the plasma treated samples were stored in covered glass containers in laboratory air environment.

Near-surface compositional depth profiling was performed using the Kratos Axis Ultra-X-ray photoelectron spectroscopy (XPS) system, equipped with a hemispherical analyzer. A 100 W monochromatic Al Kα (1 486.7 eV) beam irradiated a 1 mm×0.5 mm sampling area with a take-off angle of 90°. The pressure in the XPS chamber was held between 10⁻⁹ and 10⁻¹⁰ Torr. Elemental high resolution scans for C 1 s, F 1 s, and O 1 s were taken in the constant analyzer energy mode with a 20 eV pass energy. The calibration energy for the hydrocarbon C 1 s core level was assigned a value of 285.0 eV for the binding energy scale.

### Adhesion Tests

The adhesive strength of the polymers studied was evaluated using a T-peel testing configuration according to ASTM 1876-01. The T-peel test is a test designed to determine the peel resistance of adhesive bonds between flexible adherends. The test specimens (UHMWPE, PET, PTFE) consisted of two 15.2 cm×30.5 cm films bonded together with a urethane-based adhesive (DevThane 5, Devcon). DevThane 5 is a two-part adhesive mixed together in a 1:1 ratio. The first 7.6 cm of the film length were intentionally not bonded together in order to grip the specimen for peel testing. After mixing, the adhesive was spread onto the surface of the polymer films and they were bonded together. In the case of plasma treated specimens, the plasma treated sides were bonded together. A roller was used to remove air bubbles present in the adhesive and to ensure a uniform bondline thickness. The prepared adherends were left to cure on a flat, dry surface for 24 h at room temperature. The cured specimens were then cut into 30.5 cm×2.5 cm strips and tested. The peel tests were conducted on an MTS-Synergie electromechanical load frame fitted with a 500 N load cell. The crosshead displacement rate was 0.4 cm·s⁻¹. At least ten valid tests were conducted for each adhesive type/surface/material condition.

While the foregoing is directed to embodiments of the present invention, other and further embodiments of the invention may be devised without departing from the basic scope thereof.

1. A method for treating a surface of a substrate, comprising:
forming reactive sites on the surface of the substrate by exposing the surface of the substrate to a first atmospheric plasma formed from a first process gas comprising an inert gas; and
functionalizing the reactive sites by exposing the surface of the substrate to a second atmospheric plasma formed from a second process gas comprising the inert gas and water vapor (H₂O).

2. The method of claim 1, wherein forming the reactive sites further comprises:
removing impurities on the surface of the substrate using the first atmospheric plasma to expose the reactive sites on the surface.

3. The method of claim 1, wherein forming the reactive sites further comprises:
forming radicals on the surface of the substrate by breaking chemical bonds using the first atmospheric plasma, wherein in at least a first portion of the radicals are the reactive sites.

4. The method of claim 3, wherein forming the reactive sites further comprises:
forming protected sites by crosslinking at least a second portion of the radicals.

5. The method of claim 4, where forming the reactive sites further comprises:
controlling a ratio of reactive sites to protected sites on the surface of the substrate by adjusting one or more of flow rate of the first process gas, temperature of the substrate, density of the first atmospheric plasma, power of the first atmospheric plasma, distance between the substrate and one or more electrodes used to form the first atmospheric plasma or duration of exposure to the first atmospheric plasma.

6. The method of claim 1, wherein functionalizing the reactive sites further comprises:
removing impurities on the surface of the substrate using the second atmospheric plasma.

7. The method of claim 1, wherein functionalizing the reactive sites further comprises:
controlling a type of functional group formed at the reactive sites formed by adjusting one or more of the ratio of the inert gas to water vapor in the second process gas, the temperature of the substrate, the density of the second atmospheric plasma, power of the second atmospheric plasma, distance between the substrate and one or more electrodes used to form the second atmospheric plasma, or a duration of exposure to the second atmospheric plasma.

8. The method of claim 7, wherein the type of functional groups formed at the reactive sites includes at least one of hydroxyl groups, ketone groups, carbonyl or carboxylic acid groups.

9. The method of claim 1, further comprising:
forming a layer on the surface of the substrate by exposing the surface of the substrate to a layer forming species.

10. The method of claim 9, wherein the layer forming species is included with the second process gas and wherein exposing the surface of the substrate to the second atmospheric plasma further comprises:
exposing the surface of the substrate to a second atmospheric plasma formed from a second process gas comprising the inert gas, water vapor (H₂O) and a layer forming species to functionalize the reactive sites formed by exposure to the first atmospheric plasma and to react the functionalized reactive sites with the layer forming species to form the layer on the surface of the substrate.

11. The method of claim 9, wherein forming the layer on the surface of the substrate further comprises:
exposing the surface of the substrate to the layer forming species after exposure to the second atmospheric plasma.

12. The method of claim 9, wherein forming the layer on the surface of the substrate further comprises:
reacting the functionalized reactive sites with the layer forming species to form a bond between the functionalized reactive sites and the layer forming species.

13. The method of claim 12, wherein the layer forming species may include one or more of isocyanate, urethane, vinyl ester and epoxy-based adhesives, alkylsilanes, or perfluoroalkylsilanes.

14. The method of claim 9, wherein forming the layer on the surface of the substrate further comprises:
depositing the layer on the surface of the substrate from the layer forming species using one or more of chemical vapor deposition, physical vapor deposition, sputtering, spray deposition, casting, spin coating, or dip coating.

15. The method of claim 1, wherein the substrate comprises at least one of a polymer, a ceramic, a composite material, a hybrid material or a metal.

16. The method of claim 1, wherein the inert gas comprises at least one of helium (He), argon (Ar), neon (Ne) xenon (Xe), krypton (Kr), radon (Rn), nitrogen (N₂), hydrogen (H₂), or air.

17. A method for treating a surface of a substrate, comprising:
forming radicals on the surface of the substrate by exposing the surface to a first atmospheric plasma formed from a first process gas comprising an inert gas to break chemical bonds on the surface, wherein a first portion of the radicals form reactive sites on the surface and a second portion of the radicals form protective sites on the surface;
functionalizing the reactive sites formed by the first atmospheric plasma by exposing the surface of the substrate to a second atmospheric plasma formed from a second process gas comprising the inert gas and water vapor (H₂O); and
forming a layer on the functionalized surface of the substrate by exposing the surface of the substrate to a layer forming species during or after exposure to the second atmospheric plasma.

18. The method of claim 17, wherein exposing the surface to the first and second atmospheric plasmas further comprises
removing impurities on the surface of the substrate using the first and second atmospheric plasmas.

19. The method of claim 17, wherein forming the layer on the functionalized surface of the substrate further comprises:
depositing the layer on the functionalized surface of the substrate using one or more of chemical vapor deposition, physical vapor deposition, sputtering, spray deposition, casting, spin coating, or dip coating.

20. A method for treating a surface of a polymer substrate, comprising:
exposing a surface of polymer substrate to a first atmospheric plasma in an open atmosphere, wherein the open atmosphere comprises a first process gas comprising an inert gas to form reactive sites on the surface of the substrate and the open atmosphere temperature and first plasma process temperature range from about 20° C. to about 30° C. and the open atmosphere pressure and first plasma process pressure range from about 700 Torr to about 800 Torr;
exposing the surface of the substrate to a second atmospheric plasma formed from a second process gas comprising the inert gas and water vapor (H₂O) at a water vapor mass fraction of at least about 50 mg·g⁻¹ of gas mixture to functionalize the reactive sites wherein the open atmosphere temperature and second plasma process temperature range from about 20° C. to about 30° C., the open atmosphere pressure and second plasma process pressure range from about 700 Torr to about 800 Torr and the open atmosphere humidity and second plasma process humidity are at least about 50 percent relative humidity; and
forming a layer on the functionalized surface of the substrate by exposing the surface of the substrate to a layer forming species during or after exposure to the second atmospheric plasma
wherein the treatment increases the oxygen content of the polymer substrate surface, increases the hydrophilicity of the polymer substrate surface by at least 10 percent and increases the adhesive strength of the film as measured by T-Peel testing according to ASTM 1876-01.
